(19) United States
(12) Patent Application Publication
(10) Pub. No.: US 2024/0038750 A1
(43) Pub. Date: Feb. 1, 2024

(54) SEMICONDUCTOR MODULE

(71) Applicant: FUJI ELECTRIC CO., LTD., Kawasaki-shi (JP)

(72) Inventors: Takuma SAKAI, Matsumoto-city (JP); Seiki IGARASHI, Saitama-city (JP)

(73) Assignee: FUJI ELECTRIC CO., LTD., Kawasaki-shi (JP)

(21) Appl. No.: 18/343,117

(22) Filed: Jun. 28, 2023

(30) Foreign Application Priority Data
Jul. 29, 2022 (JP) 2022-121519

(51) Int. Cl. H01L 25/18; H01L 23/538; H02M 3/155

(52) U.S. Cl. CPC H01L 25/18; H01L 23/5386; H02M 3/155; H01L 24/48

(57) ABSTRACT

A semiconductor module includes: first and second switching devices coupled in series; a casing housing the first and second switching devices, and having first to fourth edges respectively on first to forth edge sides thereof; positive and negative terminals provided on the first edge side of the casing; an output terminal provided on the second edge side of the casing; a first control terminal and a first sense terminal for the first switching device, and a second control terminal and a second sense terminal for the second switching device, all provided on the third edge side of the casing; first and second conductive patterns respectively coupled to the positive terminal and the output terminal, and on which the first and second switching device are respectively arranged; and a third conductive pattern coupled to the negative terminal and the second switching device, on a side corresponding to the fourth edge side.

### CROSS-REFERENCE TO RELATED APPLICATION

The present application claims priority pursuant to 35 U.S.C. § 119 from Japanese patent application number 2022-121519 filed on Jul. 29, 2022, the entire disclosure of which is hereby incorporated by reference herein.

### BACKGROUND

### Technical Field

The present disclosure relates to a semiconductor module.

### Description of the Related Art

As semiconductor modules including semiconductor chips, for example, those described in Japanese Patent Application Publication Nos. 2013-118336, 2007-116840, 2018-101734, and 2009-177040 are known.

In such a semiconductor module, when variation in a current flowing through a conductive pattern (main current) is large, the influence of electromagnetic induction (noise) may cause the semiconductor module to malfunction.

### SUMMARY

An aspect of an embodiment of the present disclosure is to provide a semiconductor module, comprising: a first switching device; a second switching device coupled in series with the first switching device; a casing having a first edge, a second edge, a third edge, and a fourth edge, the first and second edges facing each other in a first direction in a plan view of the semiconductor module, the third and fourth edges facing each other in a second direction intersecting the first direction in the plan view, the casing being configured to house the first and second switching devices; a positive terminal and a negative terminal that are provided on a first edge side of the casing; an output terminal provided on a second edge side of the casing; a first control terminal a first sense terminal for the first switching device, and a second control terminal for the second switching device, and a second sense terminal for the second switching device, the first and second control terminals and the first and second sense terminals being provided on a third edge side of the casing; a first conductive pattern coupled to the positive terminal, the first switching device being arranged on the first conductive pattern; a second conductive pattern coupled to the output terminal, the second switching device being arranged on the second conductive pattern; and a third conductive pattern coupled to the negative terminal and the second switching device, the third conductive pattern being provided on one side of the semiconductor module corresponding to a fourth edge side of the casing.

### BRIEF DESCRIPTION OF THE DRAWINGS

FIG. 1 is a plan view illustrating an internal configuration of a semiconductor module 10 in a comparative example.

FIG. 2 is a diagram illustrating an equivalent circuit of a semiconductor module 10 of FIG. 1.

FIG. 3 is an explanatory diagram illustrating a situation where electromagnetic induction occurs in an area enclosed by a dashed line of FIG. 2.

FIG. 4 is a plan view illustrating an internal configuration of a semiconductor module 1 of a first embodiment.

FIG. 5 is a cross-sectional view of a semiconductor module 1 taken along a Y direction.

FIG. 6 is a diagram illustrating an equivalent circuit diagram of a semiconductor module 1 of FIG. 4.

FIG. 7 is a plan view illustrating an internal configuration of a semiconductor module 1A of a second embodiment.

FIG. 8 is a diagram illustrating an equivalent circuit of a semiconductor module 1A of FIG. 7.

FIG. 9A is a side view, FIG. 9B is a perspective view, and FIG. 9C is a plan view illustrating a third embodiment.

FIG. 10A is a side view, FIG. 10B is a perspective view, and FIG. 10C is a plan view illustrating a configuration of a modification of a third embodiment.

FIG. 11 is a diagram illustrating another modification of a third embodiment.

### DETAILED DESCRIPTION

Herein, the same or equivalent constituent elements, members, and the like illustrated in the drawings are given the same reference signs, and repetitive description thereof will be omitted for convenience. In an embodiment of the present disclosure, the term “coupling” means electrical coupling unless otherwise specified. For this reason, “coupling” includes a case where two components are coupled not only through wiring but also through a resistor, for example.

### =====First Embodiment=====

### <<Configuration of Semiconductor Module>>

A semiconductor module according to an embodiment of the present disclosure is a power module that is applied to, for example, a power converter or the like, and that includes semiconductor chips constituting an inverter circuit and the like. Prior to description of the semiconductor module according to an embodiment of the present disclosure, a comparative example will be described first.

### Comparative Example

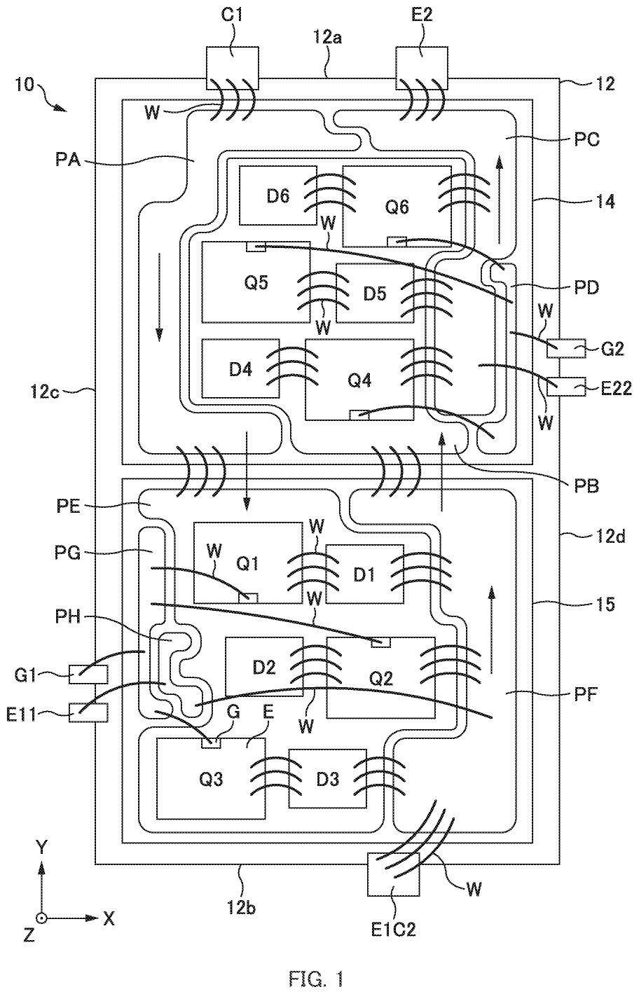

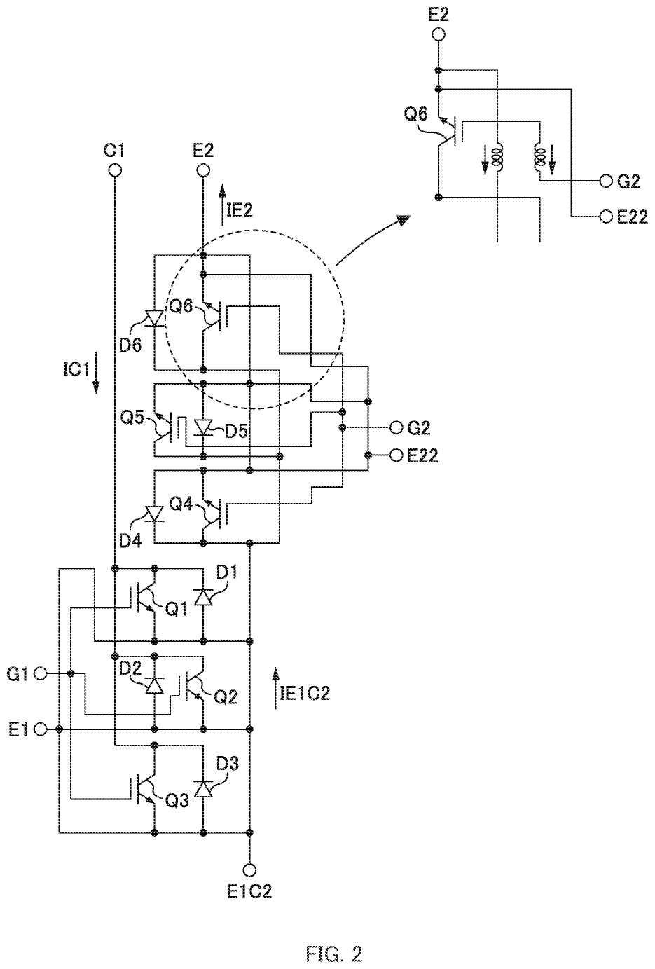

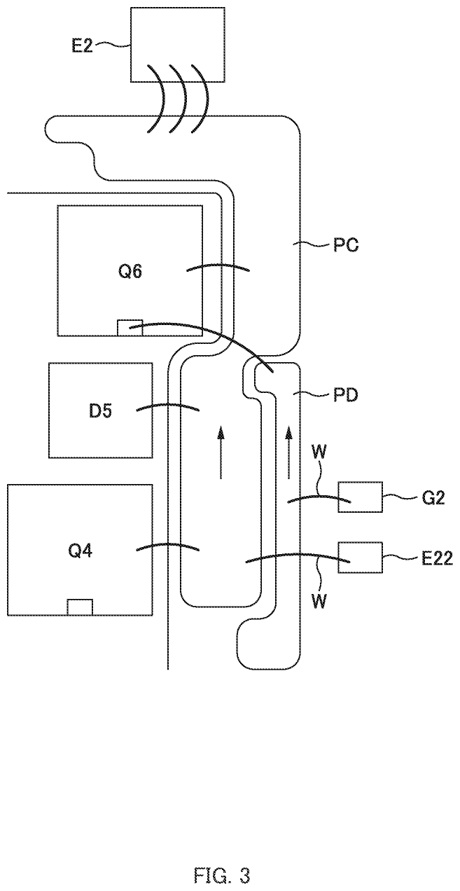

FIG. 1 is a plan view illustrating an internal configuration of a semiconductor module 10 of the comparative example. FIG. 2 is a diagram illustrating an equivalent circuit of the semiconductor module 10 of FIG. 1. FIG. 3 is an explanatory diagram illustrating a situation where electromagnetic induction occurs in an area enclosed by a dashed line of FIG. 2.

As illustrated in FIG. 1, the semiconductor module 10 has a substantially-quadrangular shape in plan view.

Herein, the term “quadrangular shape” means a shape formed of four sides, such as, for example, squares, rectangles, trapezoids, and parallelograms. Further, the “substantially-quadrangular shape” may have a shape obtained by cutting off at least one of corners thereof obliquely to a side thereof, for example. Moreover, in the “substantially-quadrangular shape”, a notch (recess) and/or a projection (protrusion) may be provided to a portion of any of sides.

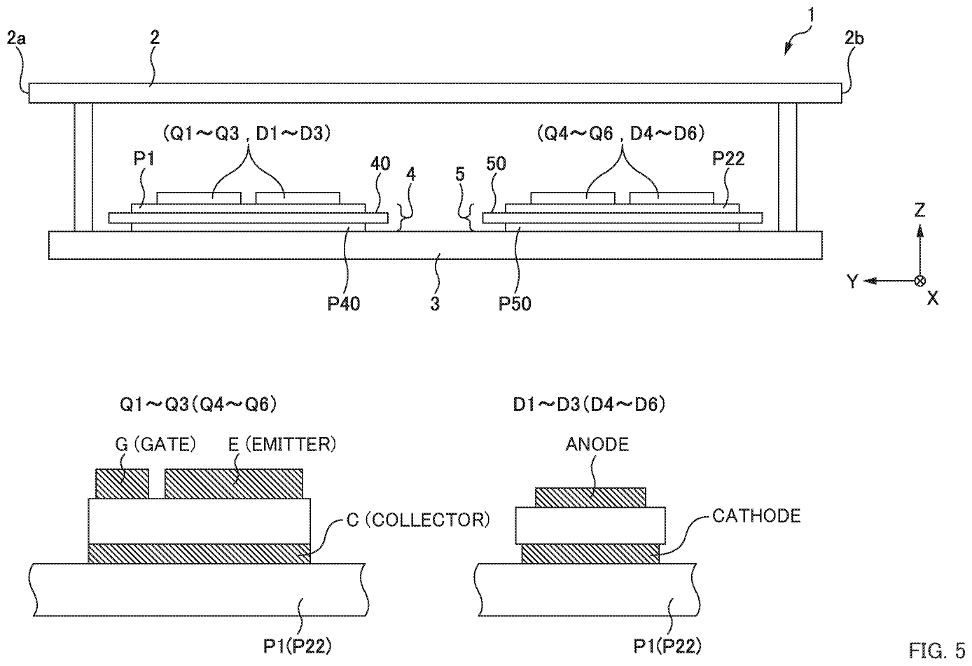

In the following description, as illustrated in the drawings, an X direction refers to a direction along the shorter side of the semiconductor module and a Y direction refers to a direction along the longer side of the semiconductor module (a direction intersecting the X direction). Further, a Z direction refers to a direction orthogonal to (intersecting) the X direction and the Y direction (see FIG. 5 and the like). It is assumed that, in each of the directions, the direction of the arrow thereof in the drawings indicate a “positive side (+ side)”, and the directions opposite thereto indicate a “negative side (− side)”, and the positive side in the Z direction is “up” and the negative side therein is “down”. FIG. 1 is the view of the semiconductor module 10 when seen from above, and illustrates an internal configuration when seen through an upper face of a casing 12, which will be described later. However, the edges of the casing 12 (edges 12a to 12d) are illustrated for the sake of explanation.

The semiconductor module 10 of the comparative example includes the casing 12, substrates 14 and 15, semiconductor chips Q1 to Q6, diodes D1 to D6, a positive terminal C1, a negative terminal E2, an output terminal E1C2, control terminals G1 and G2, and sense terminals E11 and E22.

The casing 12 (cover) houses the components constituting the semiconductor module 10 (such as the semiconductor chips Q1 to Q6). The casing 12 has a quadrangular shape in plan view, and includes two edges facing each other in the Y direction (an edge 12a on the positive side and an edge 12b on the negative side) and two edges facing each other in the X direction (an edge 12c on the negative side and an edge 12d on the positive side).

The positive terminal C1 and the negative terminal E2 are provided at portions of the casing 12 on the edge 12a side. An output terminal E1C2 is provided at a portion on the edge 12b side.

The control terminal G1 and the sense terminal E11 are provided at portions on the edge 12c side, and the control terminal G2 and the sense terminal E22 are provided at portions on the edge 12d side. The control terminal G1 is a terminal for controlling (on-off controlling) the semiconductor chips Q1 to Q3 provided at the substrate 15. The sense terminal E11 is a terminal for sense emitters of the semiconductor chips Q1 to Q3 (a terminal having an emitter potential in determining a gate-emitter potential to drive/stop the semiconductor chips Q1 to Q3). The control terminal G2 is a terminal for controlling (on-off controlling) the semiconductor chips Q4 to Q6 provided at the substrate 14, and the sense terminal E22 is a terminal for sense emitters of the semiconductor chips Q4 to Q6 (a terminal having an emitter potential in determining a gate-emitter potential to drive/stop the semiconductor chips Q4 to Q6).

The substrates 14 and 15 are, for example, direct copper bonding (DCB) substrates or active metal brazing (AMB) substrates, each of which conductive patterns of copper (Cu), aluminum (Al), or the like are formed on an insulating plate. Conductive patterns PA, PB, PC, and PD are formed at an upper surface (i.e., a front surface) of the substrate 14, meanwhile, conductive patterns PE, PF, PG, and PH are formed at an upper surface of the substrate 15. The substrate 14 is arranged on the edge 12a side (closer to the positive terminal C1 and the negative terminal E2) and the substrate 15 is arranged on the edge 12b side (closer to the output terminal E1C2).

The conductive pattern PA is coupled to the positive terminal C1 through wiring members W and is arranged to surround a region of the conductive pattern PB on the negative side in the X direction. The wiring members W are, for example, bonding wires, and a material usable therefor is any one or a combination of gold, copper, aluminum, gold alloy, copper alloy, and aluminum alloy. In an embodiment of the present disclosure, a predetermined conductive pattern and a predetermined terminal, a predetermined conductive pattern and another conductive pattern, and the like are coupled through bonding wires (wiring members W), however, the description “through bonding wires” is omitted as appropriate for convenience. In addition, the bonding wires may also be simply referred to as “wires”.

The conductive pattern PB is provided between the conductive pattern PA and the conductive pattern PC, and is coupled to the conductive pattern PF of the substrate 15. The semiconductor chips Q4 to Q6 and the diodes D4 to D6 are arranged at the front surface of the conductive pattern PB.

The conductive pattern PC is coupled to the negative terminal E2, and is arranged to surround a part of a region of the conductive pattern PB on the positive side in the X direction. The conductive pattern PC is coupled to the sense terminal E22 and the negative terminal E2.

The conductive pattern PD is a pattern for coupling the control terminal G2 and gate electrodes of the semiconductor chips Q4 to Q6. The conductive pattern PD is arranged mainly along the Y direction between the control terminal G2 and the conductive pattern PC. The conductive pattern PD is coupled to the control terminal G2 and the gate electrodes of the semiconductor chips Q4 to Q6.

The conductive pattern PE is coupled to the conductive pattern PA at the substrate 14. The semiconductor chips Q1 to Q3 and the diodes D1 to D3 are arranged at the upper surface (the front surface) of the conductive pattern PE.

The conductive pattern PF is provided on the positive side in the X direction with respect to the conductive pattern PE, and is coupled to the output terminal E1C2 and the conductive pattern PB at the substrate 14.

The conductive pattern PG is a pattern for coupling the control terminal G1 and gate electrodes of the semiconductor chips Q1 to Q3, and is coupled to the control terminal G1 and the gate electrodes of the semiconductor chips Q1 to Q3.

The conductive pattern PH is coupled to the sense terminal E11 and the conductive pattern PF.

The semiconductor chips Q1 to Q6 are insulated gate bipolar transistors (IGBTs), and each thereof includes a gate electrode, an emitter electrode, and a collector electrode. Among them, the gate electrode and the emitter electrode are formed at one surface (the upper surface herein) out of the surfaces of each of the semiconductor chips, meanwhile, the collector electrode is formed at the other surface (the lower surface herein).

The semiconductor chips Q1 to Q3 constitute a switching device for an upper arm, and are arranged on the conductive pattern PE at the substrate 15. In an embodiment of the present disclosure, the collector electrodes of the semiconductor chips Q1 to Q3 are coupled to the conductive pattern PE through a conductive material (not illustrated) such as solder.

The semiconductor chips Q4 to Q6 constitute a switching device for a lower arm, and are arranged on the conductive pattern PB at the substrate 14. In an embodiment of the present disclosure, the collector electrodes of the semiconductor chips Q4 to Q6 are coupled to the conductive pattern PB through a conductive material (not illustrated) such as solder.

The diodes D1 to D6 are freewheeling diodes (FWDs), and are arranged in parallel with the semiconductor chips Q1 to Q6, respectively. The diodes D1 to D6 each have an anode formed at one surface (the upper surface, herein) thereof, and a cathode formed at the other surface (the lower surface, herein) thereof.

The diodes D1 to D3 are arranged on the conductive pattern PE at the substrate 15. In an embodiment of the present disclosure, the cathodes of the diodes D1 to D3 are coupled to the conductive pattern PE at the substrate 15 through a conductive material (not illustrated) such as solder. The anode of the diode D1 is coupled to the emitter electrode of the semiconductor chip Q1 and the conductive pattern PF. The emitter electrode of the semiconductor chip Q2 is coupled to the anode of the diode D2 and the conductive pattern PF. The anode of the diode D3 is coupled to the emitter electrode of the semiconductor chip Q3 and the conductive pattern PF.

The diodes D4 to D6 are arranged on the conductive pattern PB at the substrate 14. In an embodiment of the present disclosure, the cathodes of the diodes D4 to D6 are coupled to the conductive pattern PB at the substrate 14 through a conductive material (not illustrated) such as solder. The emitter electrode of the semiconductor chip Q4 is coupled to the anode of the diode D4 and the conductive pattern PC. The anode of the diode D5 is coupled to the emitter electrode of the semiconductor chip Q5 and the conductive pattern PC. The emitter electrode of the semiconductor chip Q6 is coupled to the anode of the diode D6 and the conductive pattern PC.

With the above configuration, a voltage at the control terminal G1 is applied to the gate electrodes of the semiconductor chips Q1 to Q3 through the conductive pattern PG. Upon turning on of the semiconductor chips Q1 to Q3, the current flows through a path of the positive terminal C1—the conductive pattern PA—the conductive pattern PE—the semiconductor chips Q1 to Q3—the conductive pattern PF—the output terminal E1C2. Meanwhile, a voltage at the control terminal G2 is applied to the gate electrodes of the semiconductor chips Q4 to Q6 through the conductive pattern PD. Upon turning on of the semiconductor chips Q4 to Q6, the current flows through a path of the output terminal E1C2—the conductive pattern PF—the conductive pattern PB—the semiconductor chips Q4 to Q6—the conductive pattern PC—the negative terminal E2.

Here, for example, when currents flow in parallel through the conductive patterns (the conductive patterns PC and PD, herein) as illustrated in FIG. 3, and if a variation with time of the current flowing through the conductive pattern PC is great, a reverse bias voltage may be generated in the conductive pattern PD due to magnetic coupling resulting from electromagnetic induction (mutual inductance). This electromagnetic induction (e.g., electromagnetic induction illustrated in an enlarged diagram of FIG. 2) may affect (cause noise in) the gate voltage of the semiconductor chip Q6, and cause the semiconductor chip Q6 to malfunction. Note that the semiconductor chip Q6 is described herein as an example, however, other semiconductor chips may also similarly malfunction due to electromagnetic induction.

Thus, in embodiments of the present disclosure, the layout settings are changed such that such malfunctions can be suppressed.

### Embodiments of the Present Disclosure

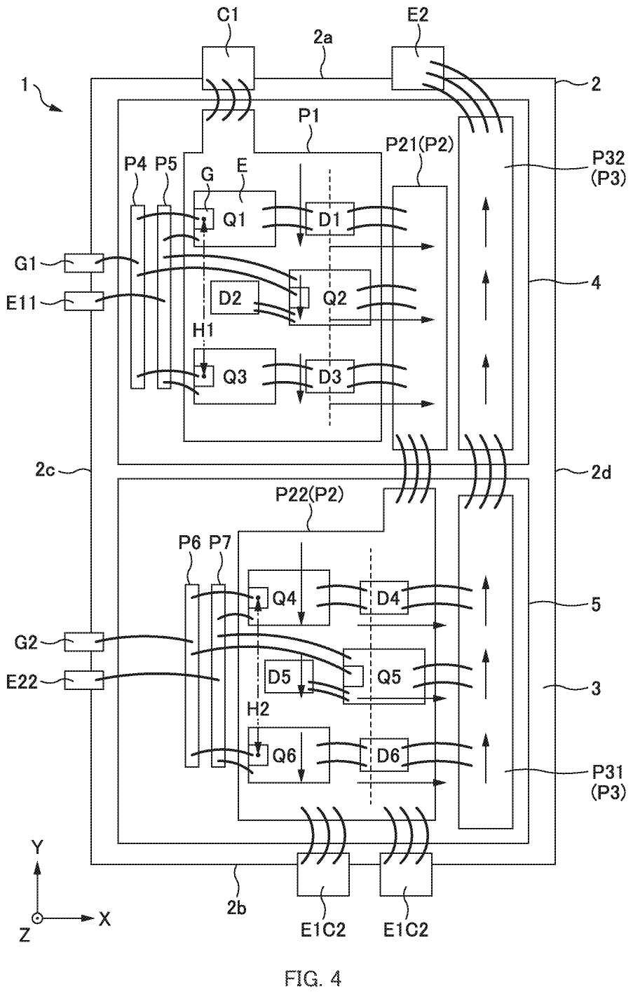

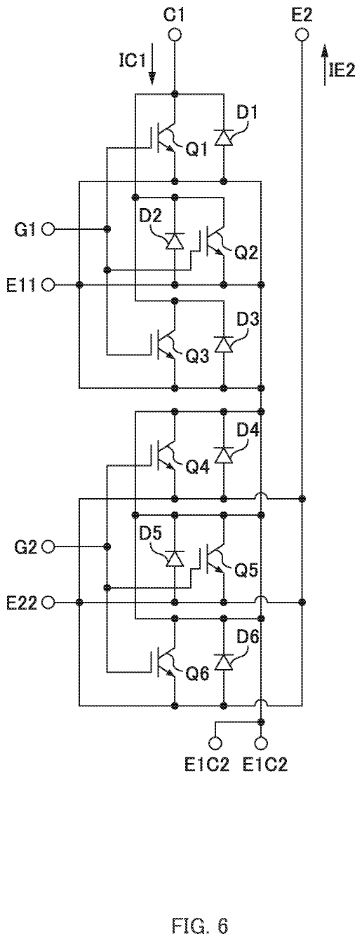

FIG. 4 is a plan view illustrating an internal configuration of a semiconductor module 1 of a first embodiment. FIG. 5 is a cross-sectional view of the semiconductor module 1 taken along a Y direction. FIG. 6 is a diagram illustrating an equivalent circuit of the semiconductor module 1 of FIG. 4. In embodiments of the present disclosure as well, an X direction, the Y direction, and a Z direction orthogonal to (intersecting) each other are defined as in the comparative example. FIG. 4 is the view of the semiconductor module 1 when seen from above, and illustrates an internal configuration when seen through an upper face of a casing 2, which will be described later. However, the edges of the casing 2 (edges 2a to 2d) are illustrated for the sake of explanation. Note that, in embodiments of the present disclosure, the Y direction corresponds to a “first direction”, the X direction corresponds to a “second direction”, and the Z direction corresponds to a “third direction”.

The semiconductor module 1 includes the casing 2, a base substrate 3, substrates 4 and 5, semiconductor chips Q1 to Q6, diodes D1 to D6, a positive terminal C1, a negative terminal E2, output terminals E1C2, control terminals G1 and G2, and sense terminals E11 and E22. The same components as in the comparative example are given the same reference signs, and the description thereof may be omitted.

The base substrate 3 is a highly-conductive large substrate made of Al, Cu, or the like, and has a shape in plan view (substantially quadrangular shape) similar to the casing 2, which will be described later. In FIG. 4, the shape of the base substrate 3 in plan view is aligned with the shape of the casing 2 in plan view (the edges 2a to 2d) for convenience. Heat sink fins (not illustrated) and the like are provided on the lower side of the base substrate 3 (the negative side in the Z direction). The substrate 4, the substrate 5, and the casing 2 (cover) are arranged on top of the base substrate 3. Note that the base substrate 3 corresponds to a “first substrate”.

The substrate 4 is, for example, a DCB substrate or an AMB substrate, in which conductive patterns (of Cu, Al, or the like) are formed on both sides of an insulating plate 40 made of an insulator (alumina, AlN, SiN, or the like). Specifically, the conductive patterns illustrated in FIG. 4 (such as a conductive pattern P1) are formed on the upper side of the insulating plate 40, and semiconductor chips Q1 to Q3 and diodes D1 to D3 are formed on the conductive pattern P1. The conductive patterns on the substrate 4 will be described later. Meanwhile, a conductive pattern P40 is formed on the lower side of the insulating plate 40, and the conductive pattern P40 is coupled to the base substrate 3. Note that the substrate 4 corresponds to a “second substrate”.

The substrate 5 has the same configuration (a DCB substrate or an AMB substrate) as that of the substrate 4. A conductive pattern P22 and the like illustrated in FIG. 4 are formed on the upper side of an insulating plate 50 of the substrate 5, and semiconductor chips Q4 to Q6 and diodes D4 to D6 are formed on the conductive pattern P22. The conductive patterns on the substrate 5 will be described later. Meanwhile, a conductive pattern P50 is formed on the lower side of the insulating plate 50, and the conductive pattern P50 is coupled to the base substrate 3. Note that the substrate 5 corresponds to a “third substrate”.

The casing 2 (cover) houses the components constituting the semiconductor module 1 (such as the semiconductor chips Q1 to Q6). Specifically, as illustrated in FIG. 5, the casing 2 according to an embodiment of the present disclosure is attached onto the base substrate 3, and houses the components, with the base substrate 3. The casing 2 has a substantially quadrangular shape in plan view, and has two edges facing each other in the Y direction (an edge 2a and an edge 2b) and two edges facing each other in the X direction (an edge 2c and an edge 2d). In the casing 2, the edge 2a corresponds to a “first edge”, the edge 2b corresponds to a “second edge”, the edge 2c corresponds to a “third edge”, and the edge 2d corresponds to a “fourth edge”. In the plan view, the substantially quadrangular shape of the casing has four sides, including respectively: a first edge side, which is a side of the casing on which the first edge thereof is located; a second edge side, which is a side of the casing on which the second edge thereof is located; a third edge side, which is a side of the casing on which the third edge thereof is located; and a fourth edge side, which is a side of the casing on which the fourth edge thereof is located.

The positive terminal C1 and the negative terminal E2 are provided at portions of the casing 2 on the edge 2a side. The output terminals E1C2 are provided at portions on the edge 2b side. The semiconductor module 1 according to an embodiment of the present disclosure is provided with two output terminals E1C2. Accordingly, the area of the output terminals E1C2 is larger than the area of each of the positive terminal C1 and the negative terminal E2. This allows a large amount of current to flow. The two output terminals E1C2 of FIG. 4 may be integrated together.

In the semiconductor module 1 of an embodiment of the present disclosure, the control terminals G1 and G2 and the sense terminals E11 and E22 are provided at portions on the edge 2c side. More specifically, the control terminal G1 and the sense terminal E11 are provided at portions adjacent to the substrate 4 (on the positive side in the Y direction with respect to the center) and the control terminal G2 and the sense terminal E22 are provided at portions adjacent to the substrate 5 (on the negative side in the Y direction with respect to the center). Note that the control terminal G1 corresponds to a “first control terminal” and the control terminal G2 corresponds to a “second control terminal”. The sense terminal E11 corresponds to a “first sense terminal” and the sense terminal E22 corresponds to a “second sense terminal”.

### (Configuration on the Substrate 4 Side)

As illustrated in FIG. 4, conductive patterns P1, P21, and P32 and control conductive patterns P4 and P5 are formed on the substrate 4 (on the insulating plate 40).

The conductive pattern P1 is coupled to the positive terminal C1. The semiconductor chips Q1 to Q3 and the diodes D1 to D3 are arranged at the conductive pattern P1. The semiconductor chips Q1 to Q3 and the diodes D1 to D3 are arranged alternately in the Y direction. This makes it possible to disperse heat generation. Note that the semiconductor chips Q1 to Q3 constitute a switching device on an upper arm side, and the switching device on the upper arm side corresponds to a “first switching device”. The conductive pattern P1 corresponds to a “first conductive pattern”.

In an embodiment of the present disclosure, IGBTs are used for such semiconductor chips each having a gate electrode and an emitter electrode formed at the upper surface (front surface) and a collector electrode formed at the lower surface (back surface), as illustrated in FIG. 5. However, the semiconductor chips are not limited to the IGBTs but may be, for example, MOSFETs. In the case of a MOSFET, a gate electrode and a source electrode thereof are formed at the upper surface, and a drain electrode thereof is formed at the lower surface.

The collector electrodes of the semiconductor chips Q1 to Q3 and the cathodes of the diodes D1 to D3 are coupled to the conductive pattern P1 through a conductive material (not illustrated) such as solder. The anode of the diode D1 is coupled to the emitter electrode of the semiconductor chip Q1 and the conductive pattern P21. The emitter electrode of the semiconductor chip Q2 is coupled to the anode of the diode D2 and the conductive pattern P21. The anode of the diode D3 is coupled to the emitter electrode of the semiconductor chip Q3 and the conductive pattern P21.

The conductive pattern P21 is coupled to the conductive pattern P22 at the substrate 5. The conductive patterns P21 and P22 constitute the conductive pattern P2. Note that the conductive pattern P2 corresponds to a “second conductive pattern”, the conductive pattern P21 corresponds to a “first section”, and the conductive pattern P22 corresponds to a “second section”.

The conductive pattern P32 is coupled to the negative terminal E2. The conductive pattern P32 is coupled to a conductive pattern P31 at the substrate 5. The conductive patterns P31 and P32 constitute the conductive pattern P3. Note that the conductive pattern P3 corresponds to a “third conductive pattern”, the conductive pattern P31 corresponds to a “third section”, and the conductive pattern P32 corresponds to a “fourth section”.

The control conductive pattern P4 is a pattern configured to couple the control terminal G1 and the gate electrodes of the semiconductor chips Q1 to Q3. The control conductive pattern P4 is arranged on the negative side in the X direction (on the edge 2c side) with respect to the conductive pattern P1, and is formed into a narrow pattern elongated in the Y direction. The length of the control conductive pattern P4 in the longitudinal direction (Y direction) is longer than a distance H1 between the geometric center of the gate electrode of the semiconductor chip Q1 arranged on the most positive side in the Y direction (on the edge 2a side) and the geometric center of the gate electrode of the semiconductor chip Q3 arranged on the most negative side in the Y direction (on the edge 2b side) in the semiconductor chips Q1 to Q3. This makes it possible to couple the control conductive pattern P4 and the gate electrodes of the semiconductor chips (semiconductor chips Q1 to Q3) along the X direction (perpendicular to a direction in which the main current flows). Note that the gate electrodes of the semiconductor chips Q1 to Q3 (and the semiconductor chips Q4 to Q6) each correspond to a “control electrode”, and the control conductive pattern P4 corresponds to a “first control conductive pattern”. The term “geometric center” means, for example, the center of the shape of the control electrode in plan view.

The control conductive pattern P5 is a pattern configured to couple the sense terminal E11 and the emitter electrodes of the semiconductor chips Q1 to Q3. The control conductive pattern P5 is provided next to the control conductive pattern P4 (between the control conductive pattern P4 and the conductive pattern P1), and is formed in the same shape as that of the control conductive pattern P4.

At the substrate 4, the above patterns are arranged in the order of the control conductive pattern P4, the control conductive pattern P5, the conductive pattern P1, the conductive pattern P21 (P2), and the conductive pattern P32 (P3) from the negative side to the positive side in the X direction. A dashed line in the conductive pattern P1 indicates a boundary between a region in which the wires (wiring members W) to the gate electrodes and the emitter electrodes of the semiconductor chips Q1 to Q3 are provided and a region in which the aforementioned wires are not provided. The current for controlling the semiconductor chips Q1 to Q3 mainly flows on the negative side in the X direction with respect to the dashed line, and the current (main current) caused by turning-on of the semiconductor chips Q1 to Q3, Q4 to Q6 mainly flows on the positive side in the X direction with respect to the dashed line (such as the conductive pattern P3).

### (Configuration on the Substrate 5 Side)

As illustrated in FIG. 4, the conductive patterns P22 and P31 and control conductive patterns P6 and P7 are formed on the substrate 5 (on the insulating plate 50).

The conductive pattern P22 is coupled to the two output terminals E1C2. The semiconductor chips Q4 to Q6 and the diodes D4 to D6 are arranged at the conductive pattern P22. Note that the semiconductor chips Q4 to Q6 constitute a switching device on a lower arm side. The switching device on the lower arm side corresponds to a “second switching device”, and is coupled in series with the switching device on the upper arm side (the first switching device).

The collector electrodes of the semiconductor chips Q4 to Q6 and the cathodes of the diodes D4 to D6 are coupled to the conductive pattern P22 through a conductive material (not illustrated) such as solder. The anode of the diode D4 is coupled to the emitter electrode of the semiconductor chip Q4 and the conductive pattern P31. The emitter electrode of the semiconductor chip Q5 is coupled to the anode of the diode D5 and the conductive pattern P31. The anode of the diode D6 is coupled to the emitter electrode of the semiconductor chip Q6 and the conductive pattern P31.

As described above, the conductive pattern P31 is coupled to the conductive pattern P32 at the substrate 4, and the conductive patterns P31 and P32 constitute the conductive pattern P3.

The control conductive pattern P6 is a pattern configured to couple the control terminal G2 and the gate electrodes of the semiconductor chips Q4 to Q6. The control conductive pattern P6 is arranged on the negative side in the X direction (on the edge 2c side) with respect to the conductive pattern P22 (P2), and is formed into a narrow pattern elongated in the Y direction. The length of the control conductive pattern P6 in the longitudinal direction (Y direction) is longer than a distance H2 between the geometric center of the gate electrode of the semiconductor chip Q4 arranged on the most positive side in the Y direction (on the edge 2a side) and the geometric center of the gate electrode of the semiconductor chip Q6 arranged on the most negative side in the Y direction (on the edge 2b side) in the semiconductor chips Q4 to Q6. This makes it possible to couple the control conductive pattern P6 and the gate electrodes of the semiconductor chips (semiconductor chips Q4 to Q6) along the X direction. Note that the control conductive pattern P6 corresponds to a “second control conductive pattern”.

The control conductive pattern P7 is a pattern configured to couple the sense terminal E22 and the emitter electrodes of the semiconductor chips Q4 to Q6. The control conductive pattern P7 is provided next to the control conductive pattern P6 (between the control conductive pattern P6 and the conductive pattern P22), and is formed in the same shape as that of the control conductive pattern P6.

In the substrate 5, the above patterns are arranged in the order of the control conductive pattern P6, the control conductive pattern P7, the conductive pattern P22 (P2), and the conductive pattern P31 (P3) from the negative side to the positive side in the X direction. A dashed line in the conductive pattern P22 indicates a boundary between a region in which the wires (wiring members W) to the gate electrodes and the emitter electrodes of the semiconductor chips Q4 to Q6 are provided and a region in which the aforementioned wires are not provided, as in the substrate 4.

With the above configuration, a voltage at the control terminal G1 is applied to the gate electrodes of the semiconductor chips Q1 to Q3 through the control conductive pattern P4. Upon turning on of the semiconductor chips Q1 to Q3, the current flows through a path of the positive terminal C1—the conductive pattern P1—the semiconductor chips Q1 to Q3—the conductive pattern P21—the conductive pattern P22—the output terminals E1C2. Meanwhile, a voltage at the control terminal G2 is applied to the gate electrodes of the semiconductor chips Q4 to Q6 through the control conductive pattern P6. Upon turning on of the semiconductor chips Q4 to Q6, the current flows through a path of the output terminals E1C2—the conductive pattern P22—the semiconductor chips Q4 to Q6—the conductive pattern P31—the conductive pattern P32—the negative terminal E2.

In an embodiment of the present disclosure, the layout of the terminals and the conductive patterns is changed, without changing the substrate size, as compared with the comparative example. Specifically, the control terminals G1 and G2 and the sense terminals E11 and E22 are provided on the edge 2c side of the casing 2. Then, the semiconductor chips Q1 to Q3 are arranged at the conductive pattern P1, and the conductive pattern P1 is coupled to the positive terminal C1. The semiconductor chips Q4 to Q6 are arranged at the conductive pattern P2, and the conductive pattern P2 is coupled to the output terminals E1C2. The conductive pattern P3 is coupled to the negative terminal E2 and the semiconductor chips Q4 to Q6, and is provided on the edge 2d side of the casing 2. This makes it possible to separate the pattern where the main current flows (the conductive pattern P3) from the control terminals G1 and G2 and the like, thereby being able to reduce the influence of electromagnetic induction and thereby suppress malfunctions.

### =====Second Embodiment=====

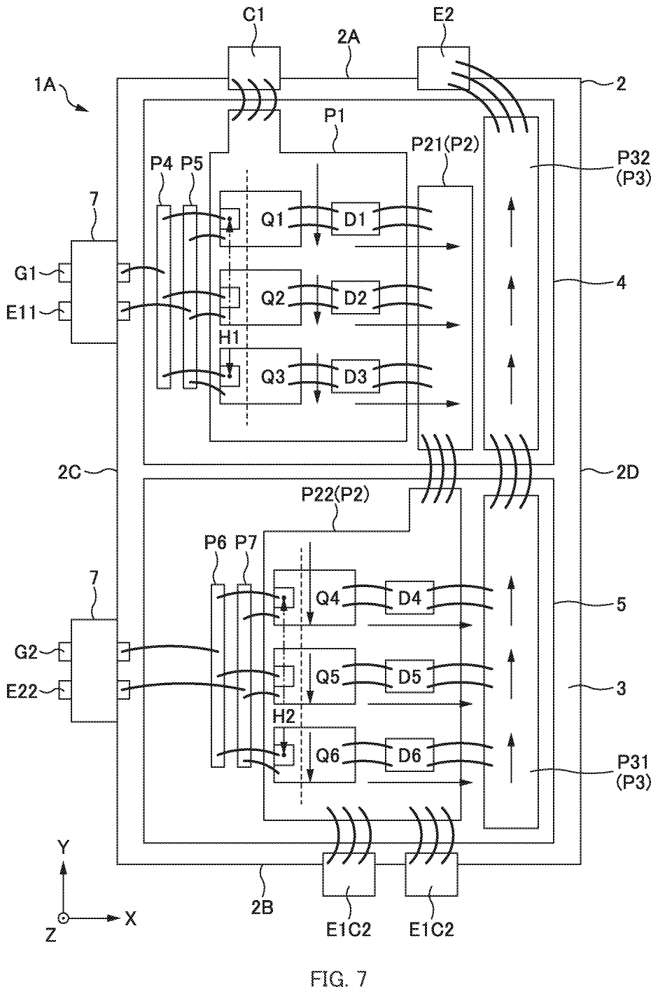

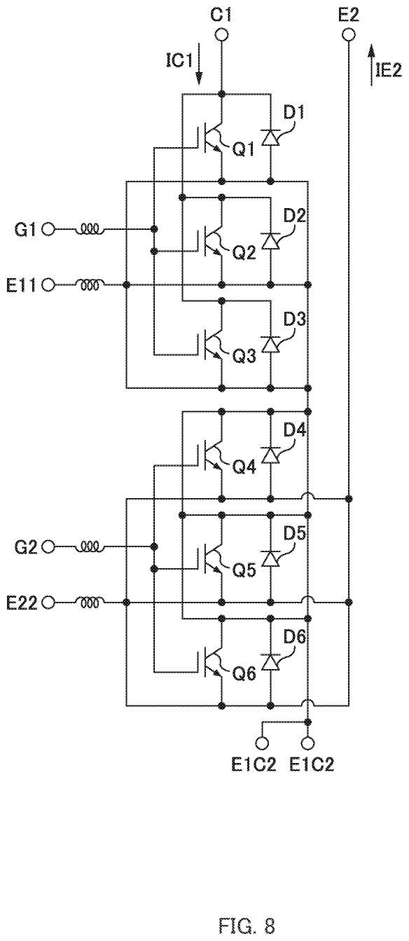

FIG. 7 is a plan view illustrating an internal configuration of a semiconductor module 1A of a second embodiment. FIG. 8 is a diagram illustrating an equivalent circuit of the semiconductor module 1A of FIG. 7. The same components as in the first embodiment are given the same reference signs in FIGS. 7 and 8, and the description thereof is omitted.

In the semiconductor module 1A according to the second embodiment, common mode cores 7 to remove common-mode noise are provided between a control terminal G1 and a sense terminal E11 and between a control terminal G2 and a sense terminal E22, respectively. Note that the common mode core 7 corresponds to a “filter”. The provision of the common mode core 7 makes it possible to suppress noise on the two terminals of the control terminal G1 (G2) and the sense terminal E11 (E22), thereby being able to determine the switch timing with high accuracy.

In the semiconductor module 1A according to the second embodiment, the layout of semiconductor chips Q1 to Q6 and diodes D1 to D6 is different from that in the foregoing embodiment. Specifically, in a substrate 4, the semiconductor chips Q1 to Q3 are arranged on the negative side in the X direction of a conductive pattern P1 and are aligned in the Y direction. Then, the diodes D1 to D3 are arranged on the positive side in the X direction of the conductive pattern P1 and are aligned in the Y direction. With such a layout, the gate-emitter wiring can be further separated from the pattern where the main current flows (the position of a dashed line of FIG. 7 is shifted to the negative side in the X direction from the position in FIG. 4). In other words, the influence of electromagnetic induction is less likely to be received.

Since the same applies to the substrate 5 side, the description thereof is omitted herein.

### =====Third Embodiment=====

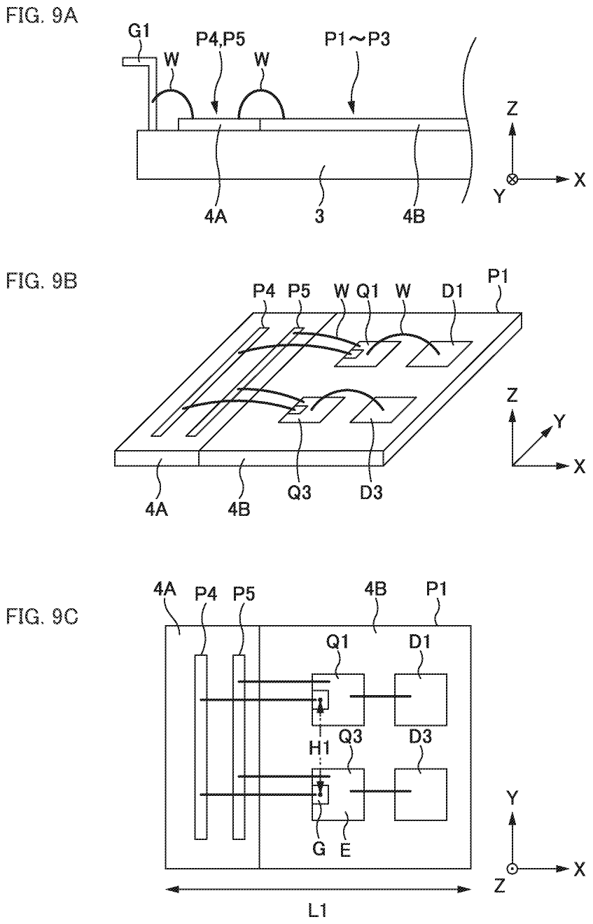

FIG. 9A is a side view, FIG. 9B is a perspective view, and FIG. 9C is a plan view of a third embodiment.

FIGS. 9A to 9C illustrate a partially-simplified configuration of a semiconductor module. The components corresponding to those in the first embodiment are given the same reference signs and the description thereof is omitted. Although the substrate 4 side will be described below, the same applies to the substrate 5 side.

As illustrated in FIG. 9A, in the third embodiment, control conductive patterns P4 and P5 and conductive patterns P1 to P3 are formed at different substrates. Specifically, the control conductive patterns P4 and P5 are formed at a control substrate 4A, meanwhile, the conductive patterns P1 to P3 are formed at a main circuit substrate 4B. The control substrate 4A and the main circuit substrate 4B are placed on a base substrate 3, and the control conductive patterns P4 and P5 are formed to be flush with the conductive patterns P1 to P3.

The main circuit substrate 4B is the same substrate (such as a DCB substrate) as the substrate 4 in the foregoing embodiments. Note that the main circuit substrate 4B corresponds to a “substrate”.

The control substrate 4A is a substrate (e.g., a printed substrate) of a type different from that of the main circuit substrate 4B, and the cost thereof is lower than that of the main circuit substrate 4B.

With the semiconductor chips and the diode devices being arranged at the main circuit substrate 4B (such as the DCB substrate) as illustrated in FIGS. 9B and 9C, heat dissipation can be ensured. Meanwhile, with the control conductive patterns P4 and P5, which less need heat dissipation, being arranged at the low-cost control substrate 4A (the printed substrate), the cost can be reduced.

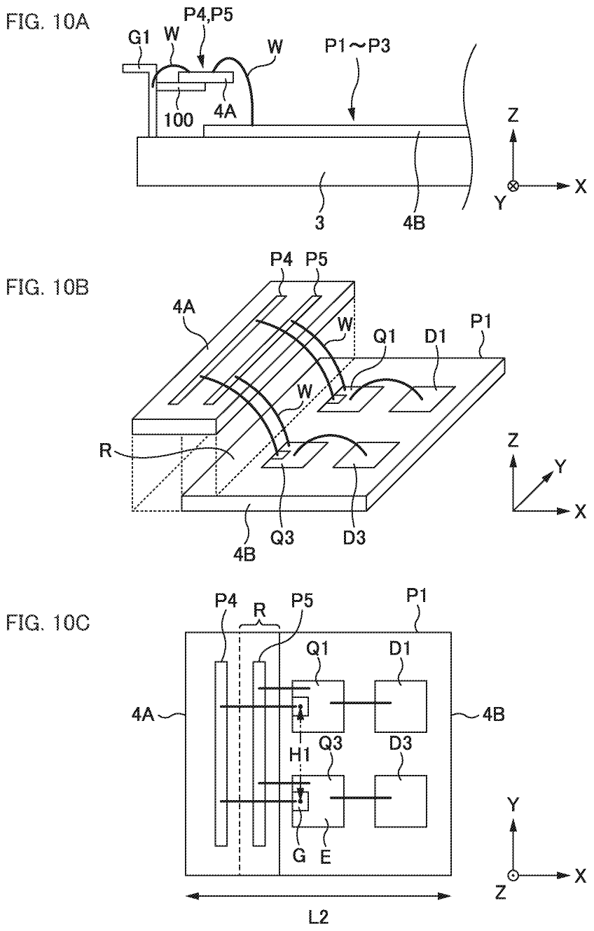

FIG. 10A is a side view, FIG. 10B is a perspective view, and FIG. 10C is a plan view illustrating a configuration of a modification of the third embodiment. FIGS. 10B and 10C illustrate only the portion corresponding to that illustrated in FIGS. 9B and 9C, respectively.

In this modification as well, the control conductive patterns P4 and P5 are formed at the control substrate 4A, meanwhile, the conductive patterns P1 to P3 are formed at the main circuit substrate 4B.

In this modification, however, the control substrate 4A is arranged at a position away from the main circuit substrate 4B in the Z direction (above the main circuit substrate 4B) as illustrated in FIGS. 10A and 10B. Specifically, a seat 100 is provided at an inner side surface of the control terminal G1, and the control substrate 4A is arranged on the seat 100. With a control section (the control conductive patterns P4 and P5) being separated upward as such, the influence of electromagnetic induction can be efficiently suppressed.

Moreover, in this modification, the control substrate 4A and the main circuit substrate 4B have an overlap region R in which these substrates overlap each other in plan view as illustrated in FIGS. 10B and 10C. Accordingly, a length L2 in the X direction in FIG. 10C is smaller than a length L1 in FIG. 9C (L2<L1). Thus, the substrate area in plan view can be reduced and the module size can be reduced accordingly. In this case as well, it is possible to suppress the influence of electromagnetic induction from the main current.

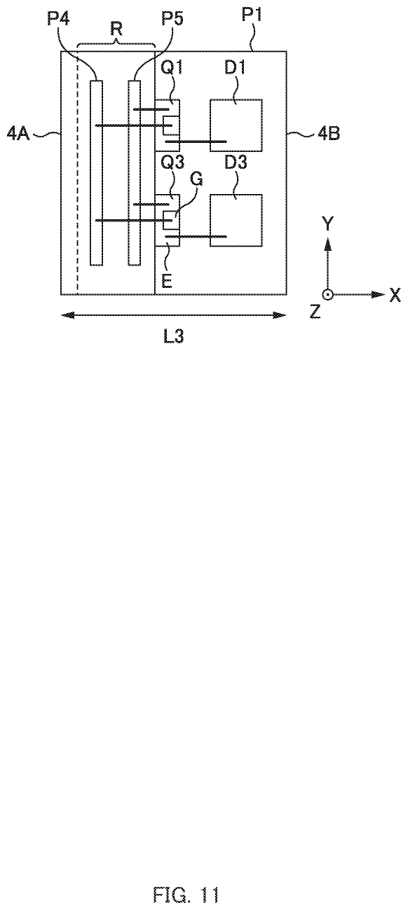

FIG. 11 is a diagram illustrating another modification of the third embodiment. In this modification, the gate electrodes of the semiconductor chips Q1 and Q3 are provided on the positive side of the X direction (on the edge 2D side of the casing 2) in the semiconductor chips Q1 and Q3. Accordingly, the control substrate 4A partially overlaps the semiconductor chips Q1 and Q3 in plan view. Thus, the overlap region R can be increased as compared with the case in FIG. 10C, and a length L3 in the X direction in FIG. 11 can be reduced further smaller than L2 in the third embodiment (FIG. 10C) (L3<L2<L1). This makes it possible to further reduce the module size.

### ===SUMMARY===

Hereinabove, the semiconductor module 1 according to an embodiment of the present disclosure has been described. The semiconductor module 1 includes the first switching device (semiconductor chips Q1 to Q3) and the second switching device (semiconductor chips Q4 to Q6) coupled in series with each other, the casing 2, the positive terminal C1, the negative terminal E2, the output terminals E1C2, the control terminals G1 and G2, the sense terminals E11 and E22, and the conductive patterns P1 to P3. The casing 2 has the edges 2a and 2b facing each other in the Y direction in plan view and the edges 2c and 2d facing each other in the Y direction in plan view, the casing 2 being configured to house the first switching device and the second switching device. The positive terminal C1 and the negative terminal E2 are provided on the edge 2a side of the casing 2, and the output terminals E1C2 are provided on the edge 2b side of the casing 2. The control terminals G1 and G2 and the sense terminals E11 and E22 are provided on the edge 2c side of the casing 2. The first switching device is arranged at the conductive pattern P1, and the conductive pattern P1 is coupled to the positive terminal C1. The second switching device is arranged at the conductive pattern P2, and the conductive pattern P2 is coupled to the output terminals E1C2. The conductive pattern P3 is coupled to the negative terminal E2 and the second switching device, and is provided on the edge 2D side of the casing 2.

This makes it possible to separate the pattern where the main current flows (third pattern) from the control terminals G1 and G2 and the like, thereby being able to reduce the influence of electromagnetic induction and thereby suppress malfunctions.

Moreover, the two output terminals E1C2 are provided to the semiconductor module 1. In plan view, the area of the output terminals E1C2 is larger than the area of each of the positive terminal C1 and the negative terminal E2.

This allows a large amount of current to flow through the output terminals E1C2.

Further, the semiconductor module includes: the control conductive pattern P4 configured to couple the control terminal G1 and the semiconductor chips Q1 to Q3; and the control conductive pattern P6 configured to couple the control terminal G2 and the semiconductor chips Q4 to Q6. The control conductive pattern P4 is arranged closer to the edge 2c (on the negative side in the X direction) than the conductive pattern P1 is, and the control conductive pattern P6 is arranged closer to the edge 2c than the conductive pattern P2 is.

This makes it possible that the influence of electromagnetic induction caused by the main current is less likely to be received.

Moreover, the length of the control conductive pattern P4 in the longitudinal direction (Y direction) is longer than the distance H1 between the geometric center of the gate electrode of the semiconductor chip Q1 and the geometric center of the gate electrode of the semiconductor chip Q3, and the length of the control conductive pattern P6 in the longitudinal direction (Y direction) is longer than the distance H2 between the geometric center of the gate electrode of the semiconductor chip Q4 and the geometric center of the gate electrode of the semiconductor chip Q6.

This makes it possible to couple the control conductive pattern P4 and the semiconductor chips Q1 to Q3 as well as the control conductive pattern P6 and the semiconductor chips Q4 to Q6 along the X direction (the direction orthogonal to the direction in which the main current flows).

Further, in the modification of the third embodiment, the control conductive pattern P4 is provided at the control substrate 4A, the conductive patterns P1 to P3 are provided at the main circuit substrate 4B, and the control substrate 4A is arranged at the position away from the main circuit substrate 4B in the Z direction.

This makes it possible to efficiently suppress the influence of electromagnetic induction.

In the modification of the third embodiment, the control substrate 4A and the main circuit substrate 4B have the overlap region R in which the control substrate 4A and the main circuit substrate 4B overlap each other in plan view.

This makes it possible to reduce the module size.

Further, in another modification of the third embodiment, the overlap region R includes at least part of the semiconductor chips Q1 to Q3.

This makes it possible to further reduce the module size.

In the above modification of the third embodiment, the gate electrodes of the semiconductor chips Q1 to Q3 are provided on the positive side of the X direction (on the edge 2D side of the casing 2) in the semiconductor chips.

This makes it possible to increase the overlap region R and reduce the module size accordingly.

Further, in the second embodiment, the common mode core 7 is provided between the control terminal G1 and the sense terminal E11, and the common mode core 7 is provided between the control terminal G2 and the sense terminal E22, the common mode core 7 being configured to remove the common-mode noise.

This makes it possible to operate such that the gate current and emitter current have the same value, thereby being able to suppress the influence of an external magnetic field.

Further, the semiconductor module 1 according to the first embodiment includes the conductive base substrate 3, and the substrates 4 and 5 that are on the base substrate 3. The conductive pattern P2 includes the conductive pattern P21 and the conductive pattern P22 coupled to each other, and the conductive pattern P3 includes the conductive pattern P31 and the conductive pattern P32 coupled to each other. The substrate 4 has the conductive pattern P1, the conductive pattern P21, the conductive pattern P32, and the semiconductor chips Q1 to Q3, and the substrate 5 has the conductive pattern P22, the conductive pattern P31, and the semiconductor chips Q4 to Q6.

This makes it possible to reduce the influence of electromagnetic induction at the substrates (substrates 4 and 5).

Further, the control conductive pattern P4, the conductive pattern P1, the conductive pattern P21, and the conductive pattern P32 are arranged at the substrate 4 in this order in the X direction, meanwhile, the control conductive pattern P6, the conductive pattern P22, and the conductive pattern P31 are arranged at the substrate 5 in this order in the X direction.

This makes it possible that the influence of electromagnetic induction caused by the main current is less likely to be received.

Further, the positive terminal C1 is coupled to the conductive pattern P1, the output terminals E1C2 are coupled to the conductive pattern P22, and the negative terminal E2 is coupled to the conductive pattern P32.

This makes it possible to pass the current through the conductive patterns.

Embodiments of the present disclosure described above are simply to facilitate understanding of the present disclosure and are not in any way to be construed as limiting the present disclosure. The present disclosure may variously be changed or altered without departing from its essential features and encompass equivalents thereof.

The shape of the semiconductor module (shape in plan view) is a substantially quadrangular shape in embodiments described above, but does not have to be a quadrangular shape. For example, a shape having five or more sides may be employed.

The control conductive patterns P4 and P5 are provided in embodiments described above, however, the control terminal G1 and the gate electrodes of the semiconductor chips Q1 to Q3 as well as the sense terminal E11 and the emitter electrodes of the semiconductor chips Q1 to Q3 may be coupled directly with wiring members W (the same applies to the substrate 5 side).

Further, each of the switching devices on the upper arm side and the lower arm side includes a plurality of (three) semiconductor chips (semiconductor chips Q1 to Q3, Q4 to Q6) in embodiments described above, however, the present disclosure is not limited to this, and the number of semiconductor chips may be two or less (e.g., one) or four or more.

The present disclosure is directed to provision of a semiconductor module capable of suppressing malfunctions.

According to the present disclosure, it is possible to provide a semiconductor module capable of suppressing malfunctions.

What is claimed is:

1. A semiconductor module, comprising:
a first switching device;
a second switching device coupled in series with the first switching device;
a casing having a first edge, a second edge, a third edge, and a fourth edge, the first and second edges facing each other in a first direction in a plan view of the semiconductor module, the third and fourth edges facing each other in a second direction intersecting the first direction in the plan view, the casing being configured to house the first and second switching devices;
a positive terminal and a negative terminal that are provided on a first edge side of the casing;
an output terminal provided on a second edge side of the casing;
a first control terminal a first sense terminal for the first switching device, and a second control terminal for the second switching device, and a second sense terminal for the second switching device, the first and second control terminals and the first and second sense terminals being provided on a third edge side of the casing;
a first conductive pattern coupled to the positive terminal, the first switching device being arranged on the first conductive pattern;
a second conductive pattern coupled to the output terminal, the second switching device being arranged on the second conductive pattern; and
a third conductive pattern coupled to the negative terminal and the second switching device, the third conductive pattern being provided on one side of the semiconductor module corresponding to a fourth edge side of the casing.

2. The semiconductor module according to claim 1, wherein
in the plan view, an area of the output terminal is larger than an area of each of the positive terminal and the negative terminal.

3. The semiconductor module according to claim 1, further comprising:
a first control conductive pattern configured to couple the first control terminal and the first switching device; and
a second control conductive pattern configured to couple the second control terminal and the second switching device, wherein
the first control conductive pattern is arranged closer to the third edge of the casing than the first conductive pattern is, and
the second control conductive pattern is arranged closer to the third edge of the casing than the second conductive pattern is.

4. The semiconductor module according to claim 3, wherein
each of the first and second switching devices has a plurality of semiconductor chips that includes
a first semiconductor chip that is closest to the first edge of the casing, and
a second semiconductor chip that is closest to the second edge of the casing,
each of the plurality of semiconductor chips having a control electrode;
a length of the first control conductive pattern in a longitudinal direction thereof is longer than a distance between
a geometric center of the control electrode of the first semiconductor chip of the first switching device, and
a geometric center of the control electrode of the second semiconductor chip of the first switching device; and
a length of the second control conductive pattern in a longitudinal direction thereof is longer than a distance between
a geometric center of the control electrode of the first semiconductor chip of the second switching device, and
a geometric center of the control electrode of the second semiconductor chip of the second switching device.

5. The semiconductor module according to claim 3, further comprising:
a substrate, and
a control substrate that is arranged at a position away, in a third direction, from the substrate, the third direction being intersecting each of the first direction and the second direction, wherein
the first to third conductive patterns are formed on the substrate, and
the first and second control conductive patterns are formed on the control substrate.

6. The semiconductor module according to claim 5, wherein the control substrate and the substrate overlap each other in the plan view to form an overlap region.

7. The semiconductor module according to claim 6, wherein at least a part of the first switching device and at least a part of the second switching device are in the overlap region in the plan view.

8. The semiconductor module according to claim 7, wherein
each of the first and second switching devices includes a semiconductor chip, which has a control electrode that is provided on a side thereof facing the fourth edge of the casing.

9. The semiconductor module according to claim 1, further comprising:
a first filter provided between the first control terminal and the first sense terminal; and
a second filter provided between the second control terminal and the second sense terminal.

10. The semiconductor module according to claim 1, further comprising:
a conductive first substrate; and
a second substrate and a third substrate that are on the first substrate, wherein
the second conductive pattern includes a first section and a second section coupled to each other,
the third conductive pattern includes a third section and a fourth section coupled to each other,
the second substrate has the first conductive pattern, the first section, the fourth section, and the first switching device formed thereon, and
the third substrate has the second section, the third section, and the second switching device formed thereon.

11. The semiconductor module according to claim 10, further comprising:
a first control conductive pattern configured to couple the first control terminal and the first switching device; and
a second control conductive pattern configured to couple the second control terminal and the second switching device, wherein
the first control conductive pattern, the first conductive pattern, the first section, and the fourth section are arranged on the second substrate in this order in the second direction, and
the second control conductive pattern, the second section, and the third section are arranged on the third substrate in this order in the second direction.

12. The semiconductor module according to claim 11, wherein
the positive terminal is coupled to the first conductive pattern,
the output terminal is coupled to the second section, and
the negative terminal is coupled to the fourth section.
